(19) United States
(12) Patent Application Publication
(10) Pub. No.: US 2011/0303936 A1
(43) Pub. Date: Dec. 15, 2011

(54) LIGHT EMITTING DEVICE PACKAGE STRUCTURE AND FABRICATING METHOD THEREOF

(76) Inventor: Shang-Yi Wu, Hsinchu City (TW)

(21) Appl. No.: 12/813,200

(22) Filed: Jun. 10, 2010

(51) Int. Cl. H01L 33/60; H01L 33/48

(52) U.S. Cl. 257/98; 438/27; 257/E33.058; 257/E33.067

(57) ABSTRACT

A light emitting device package structure is described. The light emitting device package structure includes a carrier substrate with a top surface and a bottom surface, having at least two through holes. A dielectric mirror structure is formed on the top surface of the carrier substrate, wherein the dielectric mirror structure includes laminating at least five dielectric layer groups, wherein each of the dielectric layer group includes an upper first dielectric layer having a first reflective index and an lower second dielectric layer having a second reflective index smaller than the first reflective index. A first conductive trace and a second conductive trace isolated from each other are formed on the dielectric mirror structure, respectively extending from the top surface to the bottom surface of the carrier substrate along sides of the different through holes. A light emitting device chip is mounted on the top surface of the carrier substrate.

### BACKGROUND OF THE INVENTION

1. Field of the Invention

The present invention relates to a light emitting device package structure and a method for fabricating thereof, and more particularly, relates to a light emitting device package structure with improved optical efficiency and a method for fabricating thereof.

2. Description of the Related Art

Light emitting diodes (LEDs) have low volume, good luminance efficiency and fast operating speed and as such, play an important role in many applications including illumination devices or display products. LEDs, initially, have been applied in cellular phones and small sized devices such as remote controllers. With advanced development of high brightness LEDs, LEDs are now being applied in automobiles, illumination devices and large outdoor display products. However, along with high brightness for LEDs, especially for backlight and electronic illumination applications, improvement in optical efficiency becomes more important.

As such, a novel light emitting device package structure with improved optical efficiency and a method for fabricating thereof are desirable.

### BRIEF SUMMARY OF INVENTION

The invention provides a light emitting device package structure and a method for fabricating thereof. An exemplary embodiment of the light emitting device package structure comprises: a carrier substrate with a top surface and a bottom surface, having at least two through holes; a dielectric mirror structure formed on the top surface of the carrier substrate, wherein the dielectric mirror structure comprises laminating at least five dielectric layer groups, wherein each of the dielectric layer group comprises an upper first dielectric layer having a first reflective index, and an lower second dielectric layer having a second reflective index smaller than the first reflective index; a first conductive trace and a second conductive trace isolated from each other formed on the dielectric mirror structure, respectively extending from the top surface to the bottom surface of the carrier substrate along sides of the different through holes; and a light emitting device chip mounted on the top surface of the carrier substrate, wherein the light emitting device chip has a first electrode and a second electrode electrically connecting to the first conductive trace and a second conductive trace, respectively.

An method for fabricating an exemplary embodiment of a light emitting device package structure comprises: providing a carrier substrate with a top surface and a bottom surface, wherein the carrier substrate has at least two through holes; forming a dielectric mirror structure on the top surface of the carrier substrate, wherein the dielectric mirror structure comprises laminating at least five dielectric layer groups, wherein each of the dielectric layer group comprises an upper first dielectric layer having a first reflective index, and a lower second dielectric layer having a second reflective index smaller than the first reflective index; forming a first conductive trace and a second conductive trace isolated from each other on the dielectric mirror structure, respectively extending from the top surface to the bottom surface of the carrier substrate along sides of the different through holes; and mounting a light emitting device chip on the top surface of the carrier substrate.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1 to 6 are cross sections illustrating one exemplary embodiment of steps for fabricating a light emitting device package structure of the invention.

FIGS. 7a to 7c are cross sections illustrating other exemplary embodiments of a light emitting device package structure of the invention.

FIG. 8 is an enlarged view of one exemplary embodiment of a dielectric mirror structure of a light emitting device package structure of the invention.

### DETAILED DESCRIPTION OF INVENTION

The following description is of a mode for carrying out the invention. This description is made for the purpose of illustrating the general principles of the invention and should not be taken in a limiting sense. The scope of the invention is determined by reference to the appended claims. Wherever possible, the same reference numbers are used in the drawings and the descriptions to refer the same or like parts.

The present invention will be described with respect to particular embodiments and with reference to certain drawings, but the invention is not limited thereto but is only limited by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

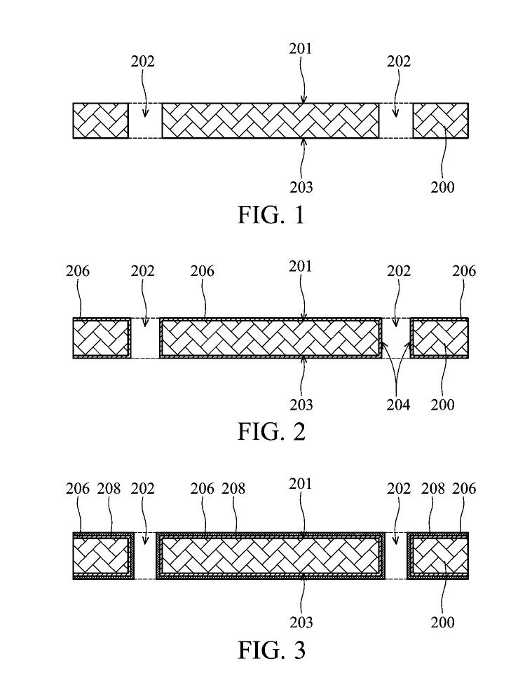

In accordance with an embodiment of the present invention, embodiments of a light emitting device package structure are provided. FIGS. 1 to 6 are cross sections illustrating one exemplary embodiment of steps for fabricating a light emitting device package structure 500a of the invention. In one embodiment, the light emitting device package structure is fabricated using a wafer level chip scale package (WLCSP) process to package a light emitting device, for example, a light emitted diode (LED) or laser diode (LD). The wafer level chip scale package process mainly means that after the package process is accomplished during the wafer stage, the wafer with chips is cut to obtain separate independent packages. However, in an embodiment of the invention, separate independent chips may be redistributed overlying a supporting wafer serving as a carrier and then packaged, which may also be referred to as a wafer scale package process. In addition, the above mentioned wafer scale package process may also be adapted to form electronic device packages of multi-layer integrated circuit devices by stacking a plurality of wafers having integrated circuits.

Referring to FIG. 1, a carrier substrate 200 having a top surface 201 and a bottom surface 203, separated by at least two through holes 202 is first provided. In one embodiment, the carrier substrate 200 may comprise a silicon substrate, semiconductor substrate, compound semiconductor substrate, semiconductor wafer, sapphire substrate, or combinations thereof. In one embodiment, the carrier substrate 200 may be a bare wafer without any electronic components, conductive wires or conductive pads thereon. The carrier substrate 200 may not only serve as a carrier supporting a subsequent mounted light emitting device chip, but also serve as a heat dissipating feature for the light emitting device chip. In one embodiment, a thinning process may be performed to thin the carrier substrate 200 to a preferred thickness by an etching, or milling process, or grinding and polishing the bottom surface 203 of the first semiconductor wafer 200. As shown in FIG. 1, through holes 202 (also referred to as through substrate vias (TSV)) are formed vertically through the carrier substrate 200 from the top surface 201 to the bottom surface 203 by patterning and etching a masking layer followed by a via wet etching, dry etching, drilling, ultrasonic milling, laser drilling, sand blasting, water jetting, deep etch, or by other mechanical/laser drilling means, or by a combined method. After the via etching process, the masking layer is removed.

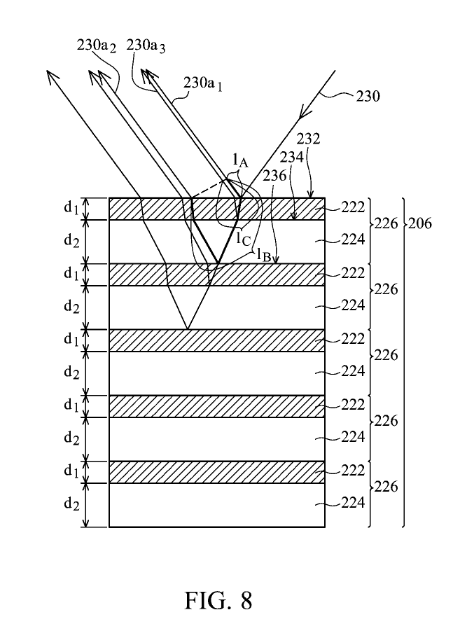

Next, referring to FIG. 2, a dielectric mirror structure 206 is conformably formed on the surface of carrier substrate 200. The dielectric mirror structure 206 extends from the top surface 201 to the bottom surface 203 of the carrier substrate 200 along sides 204 of the through holes 202. FIG. 8 is an enlarged view of one exemplary embodiment of the dielectric mirror structure 206 of a light emitting device package structure of the invention. As shown in FIG. 8, the dielectric mirror structure 206 is formed by vertically laminating at least five dielectric layer groups 226, wherein each of the dielectric layer groups 226 comprises an upper first dielectric layer 222 having a first reflective index n₁ and a lower second dielectric layer 224 having a second reflective index n₂ smaller than the first reflective index n₁. In one embodiment, the first dielectric layer 222 has a first thickness d₁ and the second dielectric layer 224 has a second thickness d₂ thicker than the first thickness d₁. In one embodiment, the dielectric mirror structure 206 may act as both, an isolating structure and a high reflection structure to improve optical efficiency through a simplified process and with low cost. When a light 230 is incident into the dielectric mirror structure 206, the light 230 can be reflected at an interface 232 between air and the first dielectric layer 222, an interface 234 between the upper first dielectric layer 222 and the lower second dielectric layer 224 of the same dielectric layer group 226 or an interface 236 between the second dielectric layer 224 of the upper dielectric layer group 226 and the first dielectric layer 222 of the lower dielectric layer group 226. The interfaces 232 and 236 are also referred to as low-to-high interfaces because the feature above the interface has a refractive index lower than the feature below the interface. Further, the interface 234 is also referred to as a high-to-low interface because the feature above the interface has a refractive index higher than the feature below the interface. In one embodiment, the reflective indexes or the thickness of the dielectric layers of the dielectric layer group 226 can be determined such that a path-length difference for lights reflected from the different low-to-high interfaces is integer multiples of a wavelength of the light, which leads to constructive interference. For example, as shown in FIG. 8, the light 230 is incident into the dielectric mirror structure 206, generating reflective lights such as a reflective light 230a₁ reflected from the low-to-high interface 232 and a reflective light 230a₂ reflected from the low-to-high interface 236. If a path-length difference between a path-length l_{A} of the reflective light 230a₁ and a path-length l_{B} of the reflective light 230a₂ is integer multiples of a wavelength of the light, a constructive interference is formed.

Additionally, the reflective lights from the high-to-low interfaces (such as the interface 234) have a 180-degree different in phase shift to the reflective lights from the low-to-high interfaces (such as the interfaces 232 and 236). Therefore, the reflective indexes or the thickness of the dielectric layers of the dielectric layer group 226 can be determined such that a path-length difference of the reflective lights between the low-to-high interface and the high-to-low interface is half an integer of a wavelength of the light, which also results in constructive interference. For example, as shown in FIG. 8, if a path-length difference between a path-length l_{B} of the reflective light 230a₂ (light reflected from the low-to-high interface) and a path-length l_{C} of the reflective light 230a₃ (light reflected from the high-to-low interface) is half an integer of a wavelength of the light, constructive interference is formed.

In one embodiment, the first dielectric layer 222 and the second dielectric layer 224 of the dielectric mirror structure 206 may comprise epoxy, silicon oxide, solder mask, or any other suitable dielectric materials, such as silicon nitride, silicon oxinitride, metal oxide, polyimide, benzocyclobutene (BCB™), parylene, polynaphthalenes, fluorocarbons or accrylates. The first dielectric layer 222 and the second dielectric layer 224 of the dielectric mirror structure 206 may be formed by a spin coating process, or may be formed by any suitable method, such as a spray coating, curtain coating, liquid phase deposition, physical vapor deposition (PVD), chemical vapor deposition (CVD), low pressure chemical vapor deposition (LPCVD), plasma enhanced chemical vapor deposition, rapid thermal chemical vapor deposition or atmospheric pressure chemical vapor deposition (APCVD) process.

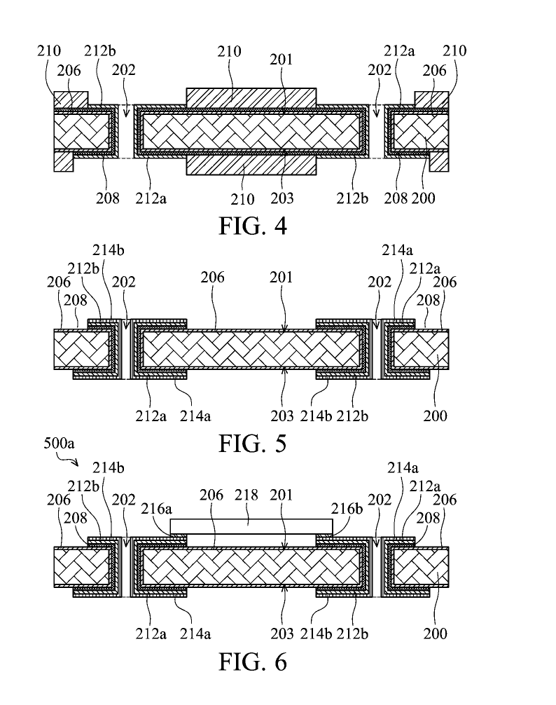

Next, as shown in FIG. 3, a conductive seed layer 208 is conformably formed on the dielectric mirror structure 206, extending from the top surface 201 to the bottom surface 203 of the carrier substrate 200 along sides 204 of the through holes 202. As shown in FIG. 4, a plurality of mask layers 210, for example, photoresist layers, are then formed covering a portion of the conductive seed layer 208 to define formation positions of subsequent conductive traces. Next, at least two separated first and second conductive traces 212a and 212b are conformably formed on the conductive seed layer 208 not covered by the mask layers 210. The first and second conductive traces 212a and 212b extend from the top surface 201 to the bottom surface 203 of the carrier substrate 200 along sides 204 of the different through holes 202. In one embodiment, the first and second conductive traces 212a and 212b are used to transmit input/output (I/O) signals, ground signals, and power signals of the subsequent light emitting chips. For example, the first and second conductive traces 212a and 212b may be comprised of metal layers or metal alloy layers such as a Ni layer, a Ag layer, a Al layer, a Cu layer or alloy layers thereof. Also, the first and second conductive traces 212a and 212b may comprise doped polysilicon, single crystalline silicon, conductive glasses and so on. Additionally, the first and second conductive traces 212a and 212b comprising metal layers may be combined with annealing metals such as Ti, Mo, Cr, TiW and so on.

As shown in FIG. 5, in one embodiment, at least two separated under bump metallurgy (UBM) layers 214a and 214b, for example, Ni/Au layers, may be partially or entirely formed on a surface of the first and second conductive traces 212a and 212b. The UBM layers 214a and 214b extend from the top surface 201 to the bottom surface 203 of the carrier substrate 200 along sides 204 of the different through holes 202, respectively. In one embodiment, the UBM layer 214a and 214b may be formed by an electroplating, electroless plating or physical vapor deposition (PVD) process. The mask layers 210 and the conductive seed layer 208 directly under the mask layers 210 as shown in FIG. 4 are removed after forming the UBM layers 214a and 214b.

Next, as shown in FIG. 6, a light emitting device chip 218 is mounted on the top surface 201 of the carrier substrate 200, wherein the light emitting device chip 218 has a first electrode 216a and a second electrode 216b electrically connected to the first conductive trace 212a and the second conductive trace 212b, respectively. Next, referring to the FIG. 6 again, the carrier substrate 200 is cut along the through holes 202 to divide the carrier substrate 200 into a plurality of light emitting device package structures 500a.

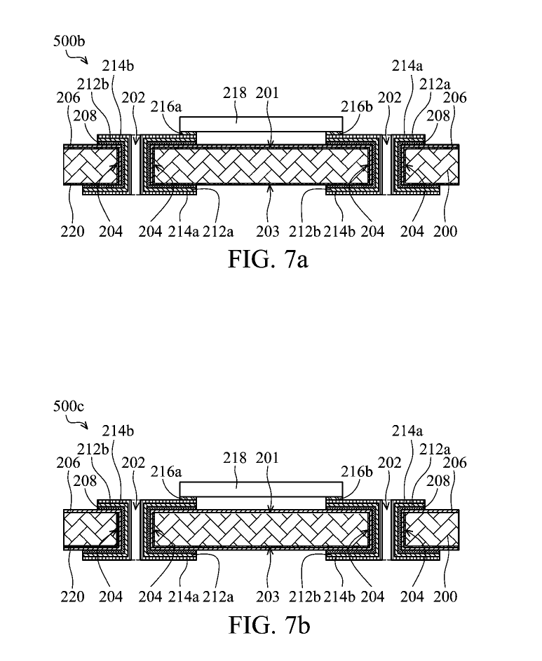

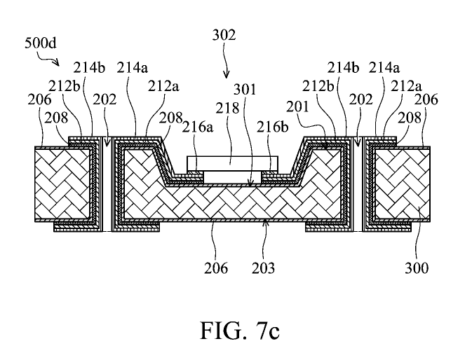

FIGS. 7a to 7c are cross sections illustrating other exemplary embodiments of light emitting device package structures 500b and 500d of the invention. Elements of the embodiments hereinafter, that are the same or similar as those previously described with reference to FIGS. 1 to 6, are not repeated for brevity. In a light emitting device package structure 500b as shown in FIG. 7a, the dielectric mirror structure 206 is formed on the top surface 201 of the carrier substrate 200 and on sides 204 of the through holes 202. Before forming the dielectric mirror structure 206, an insulating layer 220 is conformably formed on the carrier substrate 200. The insulating layer 220 extends from the top surface 201 to the bottom surface 203 of the carrier substrate 200 along sides 204 of the through holes 202. In one embodiment, the insulating layer 220 may comprise epoxy, silicon oxide, solder mask, or any other suitable dielectric materials, such as silicon nitride, silicon oxinitride, metal oxide, polyimide, benzocyclobutene (BCB™), parylene, polynaphthalenes, fluorocarbons or accrylates. The insulating layer 220 may be formed by spin coating, or may be formed by any suitable method, such as a spray coating, curtain coating, liquid phase deposition, physical vapor deposition, chemical vapor deposition, low pressure chemical vapor deposition, plasma enhanced chemical vapor deposition, rapid thermal chemical vapor deposition or atmospheric pressure chemical vapor deposition process.

In a light emitting device package structures 500c as shown in FIG. 7b, before forming the dielectric mirror structure 206, an insulating layer 220 is conformably formed on the bottom surface 203 of the carrier substrate 200 and on sides 204 of the through holes 202. Next, the dielectric mirror structure 206 is conformably formed on the carrier substrate 200, covering the insulating layer 220.

FIG. 7c, illustrates yet another exemplary embodiment of light emitting device package structure 500d. As shown in FIG. 7c, the light emitting device package structure 500d may comprise a carrier substrate 300 having a cavity 302 (also referred to as a cavity substrate 300), and the light emitting device chip 218 may be mounted on the carrier substrate 300 in the cavity 302. The dielectric mirror structure 206 is formed wrapping the carrier substrate 300, so that an inner sidewall 301 of the cavity 302 is covered by the dielectric mirror structure 206. Additionally, the conductive seed layer 208, first and second conductive traces 212a and 212b and UBM layer 214a and 214b cover a portion of the inner sidewall 301 of the cavity 302. The inner sidewall 301 of the cavity 302 between the first electrode 216a and the second electrode 216b is only covered by the dielectric mirror structure 206. Similarly to the light emitting device package structure 500b as shown in FIG. 7a, the dielectric mirror structure 206 may be formed on the top surface 201, the inner sidewall 301 of the cavity 302 and on sides 204 of the through holes 202 but not formed on the bottom surface 203 of the carrier substrate 300. Further, similarly to the light emitting device package structure 500c as shown in FIG. 7b, before forming the dielectric mirror structure 206, the insulating layer 220 is conformably formed on the bottom surface 203 and the inner sidewall 301 of the cavity 302 of the carrier substrate 300 and on sides 204 of the through holes 202. The dielectric mirror structure 206 is then conformably formed on the carrier substrate 300, covering the insulating layer 220.

One exemplary embodiment of the light emitting device package structure comprises: a carrier substrate with a top surface and a bottom surface, having at least two through holes; a dielectric mirror structure formed on the top surface of the carrier substrate, wherein the dielectric mirror structure comprises laminating at least five dielectric layer groups, wherein each of the dielectric layer group comprises an upper first dielectric layer having a first reflective index; and an lower second dielectric layer having a second reflective index smaller than the first reflective index; a first conductive trace and a second conductive trace isolated from each other formed on the dielectric mirror structure, respectively extending from the top surface to the bottom surface of the carrier substrate along sides of the different through holes; and a light emitting device chip mounted on the top surface of the carrier substrate, wherein the light emitting device chip has a first electrode and a second electrode electrically connecting to the first conductive trace and a second conductive trace, respectively.

Some advantages of the exemplary embodiment of the light emitting device package structure of the invention are described as follows. The light emitting device package structure provides a dielectric mirror structure between the carrier substrate and the conductive traces by vertically laminating at least five dielectric layer groups on the carrier substrate, wherein each of the dielectric layer groups comprises an upper first dielectric layer having a first reflective index n₁ and an lower second dielectric layer having a second reflective index n₂ smaller than the first reflective index n₁. The dielectric mirror structure may act as both an isolating structure and a high reflection structure to improve optical efficiency through a simplified process and with low cost. The reflective indexes or the thickness of the dielectric layers of the dielectric layer group can be determined such that a path-length difference for lights reflected from the different low-to-high interfaces is integer multiples of a wavelength of the light, thus resulting in constructive interference. Further, the reflective indexes or the thickness of the dielectric layers of the dielectric layer group can be determined such that a path-length difference of the reflective lights between the low-to-high interface and the high-to-low interface is half the integer multiples of a wavelength of the light, thus, also resulting in constructive interference. The carrier substrate may not only serve as a carrier supporting a subsequent mounted light emitting device chip, but also serve as a heat dissipating feature for the light emitting device chip. The light emitting device package structure is fabricated using a wafer level chip scale package (WLCSP) process to package a light emitting device. Therefore, the light emitting device package structure has much smaller dimensions than that of the conventional wire-bonding type light emitting device package structure.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting device package structure, comprising:
a carrier substrate with a top surface and a bottom surface, having at least two through holes;
a dielectric mirror structure formed on the top surface of the carrier substrate, wherein the dielectric mirror structure comprises laminating at least five dielectric layer groups, wherein each of the dielectric layer group comprises:
an upper first dielectric layer having a first reflective index; and
an lower second dielectric layer having a second reflective index smaller than the first reflective index;
a first conductive trace and a second conductive trace isolated from each other formed on the dielectric mirror structure, respectively extending from the top surface to the bottom surface of the carrier substrate along sides of the different through holes; and
a light emitting device chip mounted on the top surface of the carrier substrate.

2. The light emitting device package structure as claimed in claim 1, wherein the dielectric mirror structure extends from the top surface to the bottom surface of the carrier substrate along sides of the different through holes.

3. The light emitting device package structure as claimed in claim 1, further comprising an insulating layer formed between the carrier substrate and the dielectric mirror structure.

4. The light emitting device package structure as claimed in claim 3, wherein the insulating layer extends from the top surface to the bottom surface of the carrier substrate along sides of the different through holes.

5. The light emitting device package structure as claimed in claim 1, further comprising an insulating layer formed on the bottom surface of the carrier substrate, between the carrier substrate and the first conductive trace or the second conductive trace.

6. The light emitting device package structure as claimed in claim 1, wherein the first dielectric layer has a first thickness and the second dielectric layer has a second thickness thicker than the first thickness.

7. The light emitting device package structure as claimed in claim 1, wherein a path-length difference between lights reflected from different interfaces between the second dielectric layer of the upper dielectric layer group and the first dielectric layers of the lower dielectric layer group is integer multiples of a wavelength of the light.

8. The light emitting device package structure as claimed in claim 1, wherein a path-length difference between a light reflected from an interface between the second dielectric layer of the upper dielectric layer group and the first dielectric layers of the lower dielectric layer group and another light reflected from an interface between the first and second dielectric layers of the same dielectric layer group is half integer of a wavelength of the light.

9. The light emitting device package structure as claimed in claim 1, wherein the light emitting device chip has a first electrode and a second electrode electrically connecting to the first conductive trace and a second conductive trace, respectively.

10. The light emitting device package structure as claimed in claim 1, wherein the carrier substrate having a cavity and the light emitting device chip is mounted in the cavity.

11. A method for fabricating a light emitting device package structure comprising:
providing a carrier substrate with a top surface and a bottom surface, wherein the carrier substrate has at least two through holes;
forming a dielectric mirror structure on the top surface of the carrier substrate, wherein the dielectric mirror structure comprises laminating at least five dielectric layer groups, wherein each of the dielectric layer group comprises:
an upper first dielectric layer having a first reflective index; and
an lower second dielectric layer having a second reflective index smaller than the first reflective index;
forming a first conductive trace and a second conductive trace isolated from each other on the dielectric mirror structure, respectively extending from the top surface to the bottom surface of the carrier substrate along sides of the different through holes; and
mounting a light emitting device chip on the top surface of the carrier substrate.

12. The method for fabricating a light emitting device package structure as claimed in claim 11, wherein the dielectric mirror structure extends from the top surface to the bottom surface of the carrier substrate along sides of the different through holes.

13. The method for fabricating a light emitting device package structure as claimed in claim 11, further comprising forming an insulating layer on the carrier substrate before forming the dielectric mirror structure.

14. The method for fabricating a light emitting device package structure as claimed in claim 13, wherein the insulating layer extends from the top surface to the bottom surface of the carrier substrate along sides of the different through holes.

15. The method for fabricating a light emitting device package structure as claimed in claim 11, further comprising forming an insulating layer on the bottom surface of the carrier substrate before forming the dielectric mirror structure, wherein the insulating layer is between the carrier substrate and the first conductive trace or the second conductive trace.

16. The method for fabricating a light emitting device package structure as claimed in claim 11, wherein the first dielectric layer has a first thickness and the second dielectric layer has a second thickness thicker than the first thickness.

17. The method for fabricating a light emitting device package structure as claimed in claim 11, wherein a path-length difference between lights reflected from different interfaces between the second dielectric layer of the upper dielectric layer group and the first dielectric layers of the lower dielectric layer group is integer multiples of a wavelength of the light.

18. The method for fabricating a light emitting device package structure as claimed in claim 11, wherein a path-length difference between a light reflected from an interface between the second dielectric layer of the upper dielectric layer group and the first dielectric layers of the lower dielectric layer group and another light reflected from an interface between the first and second dielectric layers of the same dielectric layer group is half integer of a wavelength of the light.

19. The method for fabricating a light emitting device package structure as claimed in claim 11, wherein the light emitting device chip has a first electrode and a second electrode electrically connecting to the first conductive trace and a second conductive trace, respectively.

20. The method for fabricating a light emitting device package structure as claimed in claim 11, wherein the carrier substrate having a cavity and the light emitting device chip is mounted in the cavity.
